(19) United States
(12) Patent Application Publication
(10) Pub. No.: US 2014/0378192 A1
(43) Pub. Date: Dec. 25, 2014

(54) WATERPROOF PORTABLE ELECTRONIC DEVICE WITHOUT CONNECTING HOLE

(71) Applicant: COREMATE TECHNICAL CO., LTD., Taoyuan (TW)

(72) Inventor: Robert WANG, Taoyuan (TW)

(21) Appl. No.: 13/923,900

(22) Filed: Jun. 21, 2013

(51) Int. Cl. H05K 7/14; H04B 1/38

(52) U.S. Cl. CPC H05K 7/14; H04B 1/3888
USPC 455/575.8; 361/679.01; 361/679.55

(57) ABSTRACT

A waterproof portable electronic device without a connecting hole includes a portable main body and at least one induction coil. The portable main body is completely sealed and does not have any exterior connecting hole. The portable main body includes a control circuit therein. The induction coil is disposed in the portable main body and electrically connected with the control circuit. Thereby, the induction coil of the waterproof portable electronic device cooperates with an induction coil of an external charging device or an external access device to transmit power and/or data through the way of electromagnetic induction, without arrangement of connecting ports. The portable main body is completely sealed and does not have any exterior connecting hole to achieve waterproof and dust proof effects.

### BACKGROUND OF THE INVENTION

1. Field of the Invention

The present invention relates to a portable electronic device, and more particularly to a waterproof portable electronic device without a connecting hole.

2. Description of the Prior Art

There are many innovated and improved portable electronic products on the market, such as notebook computers for people to deal with their business anywhere, USB drives for people to take along with electronic data, smart phones for people to surf the Internet, play games, get e-mails and so on. The portable electronic products play an important role in these days.

The aforesaid portable electronic products usually have a charging port, a USB connecting port, an earpiece port and so on to connect with other devices for power and/or data transmission. Thus, the casings of the portable electronic products must have corresponding connecting holes for the connecting ports. This causes water and dust to enter the portable electronic products easily through the connecting holes to damage the portable electronic products. Accordingly, the inventor of the present invention has devoted himself based on his many years of practical experiences to solve these problems.

### SUMMARY OF THE INVENTION

The primary object of the present invention is to provide a waterproof portable electronic device without a connecting hole. There is no need for the waterproof portable electronic device to have connecting ports. The portable main body is completely sealed and does not have any exterior connecting hole to achieve waterproof and dust proof effects.

In order to achieve the aforesaid object, the waterproof portable electronic device without a connecting hole of the present invention comprises a portable main body and at least one induction coil. The portable main body is completely sealed and does not have any exterior connecting hole. The portable main body comprises a control circuit therein. The induction coil is disposed in the portable main body and electrically connected with the control circuit.

Thereby, the induction coil of the waterproof portable electronic device cooperates with an induction coil of an external charging device or an external access device to transmit power and/or data through the way of electromagnetic induction, without arrangement of connecting ports. The portable main body is completely sealed and does not have any exterior connecting hole to achieve waterproof and dust proof effects.

### BRIEF DESCRIPTION OF THE DRAWINGS

FIG. 1 is an exploded view according to a first embodiment of the present invention;

FIG. 2 is a sectional view according to the first embodiment of the present invention;

FIG. 3 is a schematic view of the first embodiment of the present invention when in use;

FIG. 4 is a schematic view of the first embodiment of the present invention in another use state; and

FIG. 5 is a perspective view according to a second embodiment of the present invention.

### DETAILED DESCRIPTION OF THE PREFERRED EMBODIMENTS

Embodiments of the present invention will now be described, by way of example only, with reference to the accompanying drawings.

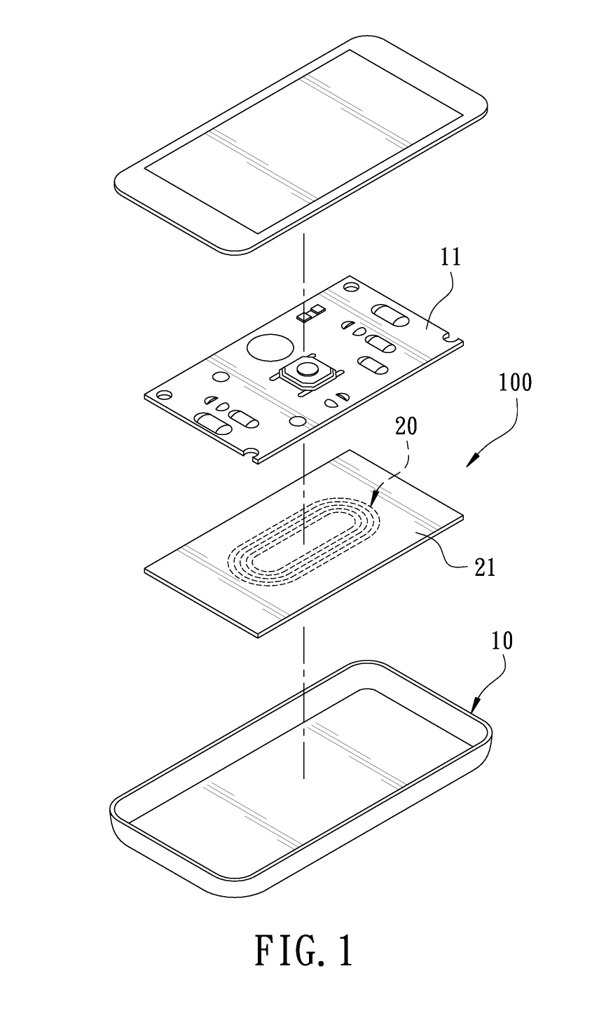

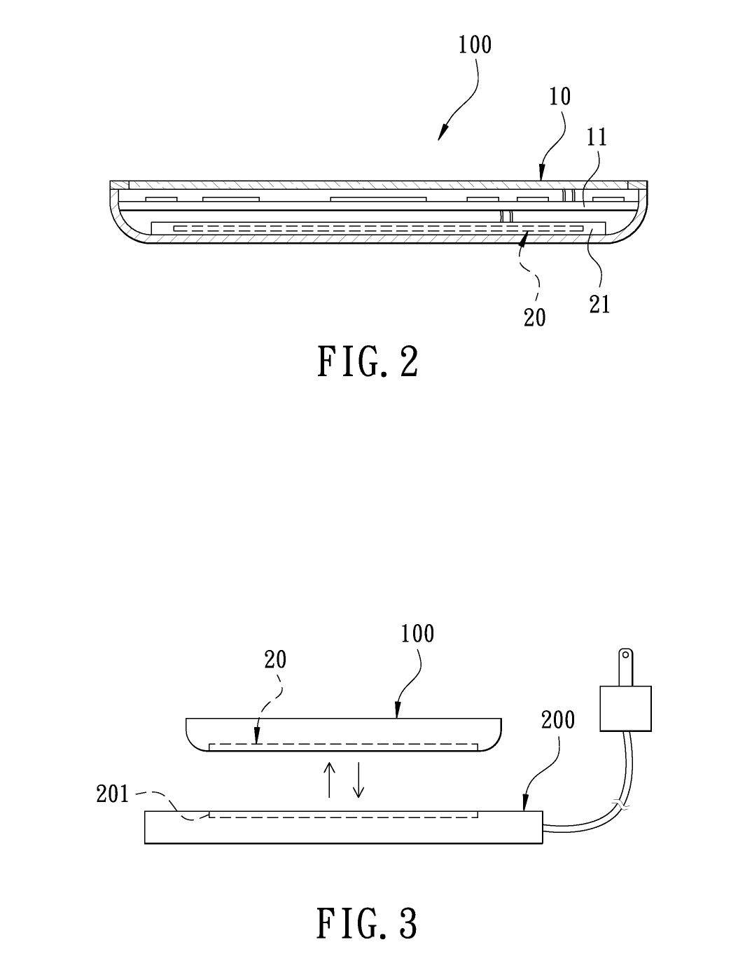

FIG. 1 is an exploded view according to a first embodiment of the present invention. FIG. 2 is a sectional view according to the first embodiment of the present invention. The present invention discloses a waterproof portable electronic device 100 without a connecting hole. The waterproof portable electronic device 100 comprises a portable main body 10 and at least one induction coil 20.

The portable main body 10 is completely sealed and does not have any exterior connecting hole. In this embodiment, the portable main body 10 is a mobile phone. The portable main body 10 comprises a control circuit 11 therein for operating the portable main body 10.

The induction coil 20 is disposed in the portable main body 10 and electrically connected with the control circuit 11. In this embodiment, the waterproof portable electronic device 100 without a connecting hole has one induction coil 20. The induction coil 20 is disposed in the portable main body 10. A protective casing 21 is provided to cover the induction coil 20.

FIG. 3 is a schematic view of the first embodiment of the present invention when in use. The waterproof portable electronic device 100 without a connecting hole is placed on an external charging device 200 which has an induction coil 201, and then the external charging device 200 is switched on. By using the induction coil 201 of the external charging device 200, the electric power is transformed into magnetic force for the induction coil 20 in the portable main body 10 to generate electric power by magnetism excitation according to Faraday's principle of electromagnetic induction, achieving wireless power transmission.

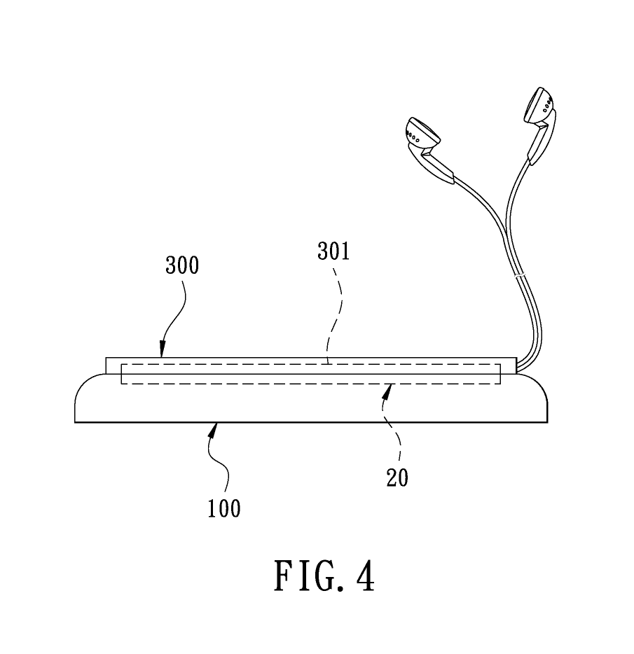

FIG. 4 is a schematic view of the first embodiment of the present invention in another use state. The waterproof portable electronic device 100 without a connecting hole is placed on an external access device 300 which has an induction coil 301, such as earphones in this embodiment, and then the external access device 300 is switched on. The induction coil 301 of the external excess device 300 and the induction coil 20 in the portable main body 10 can transmit data through the way of electromagnetic induction, achieving wireless data transmission.

Thereby, there is no need for the waterproof portable electronic device 100 to have a charging port, an earpiece port and the like. The portable main body 10 is completely sealed and does not have any exterior connecting hole to achieve waterproof and dust proof effects.

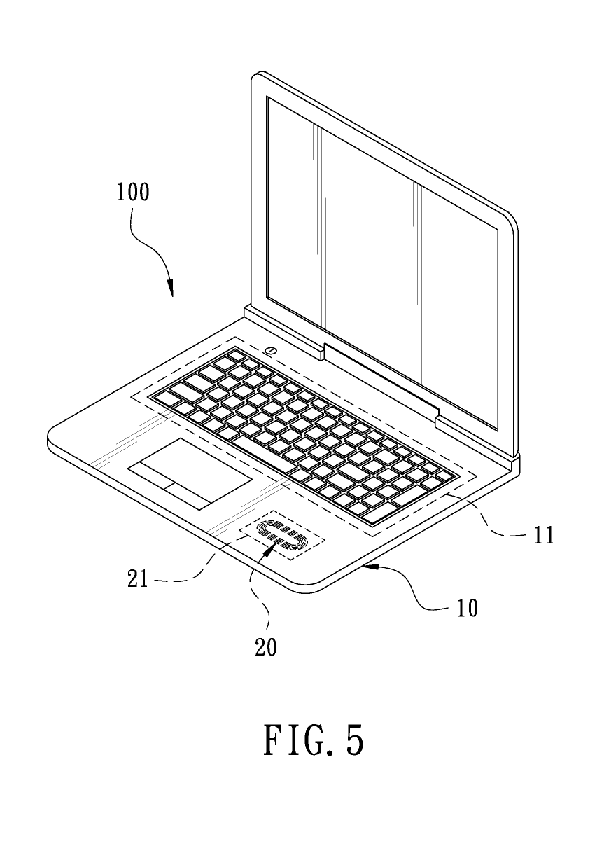

FIG. 5 is a perspective view according to a second embodiment of the present invention. The waterproof portable electronic device 100 without a connecting hole in this embodiment is substantially similar to the first embodiment with exceptions described hereinafter. In this embodiment, the portable main body 10 is a notebook computer. Similarly, the induction coil 20 uses electromagnetic induction to transmit power and date. The portable main body 10 is completely sealed and does not have any exterior connecting hole to achieve waterproof and dust proof effects.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A waterproof portable electronic device without a connecting hole, comprising:
a portable main body, the portable main body being completely sealed and not having any exterior connecting hole, the portable main body comprising a control circuit therein; and
at least one induction coil, the induction coil being disposed in the portable main body and electrically connected with the control circuit.

2. The waterproof portable electronic device without a connecting hole as claimed in claim 1, wherein a protective casing is provided to cover the induction coil.

3. The waterproof portable electronic device without a connecting hole as claimed in claim 1, wherein the portable main body is a mobile phone.

4. The waterproof portable electronic device without a connecting hole as claimed in claim 1, wherein the portable main body is a notebook computer.
